(19) United States
(12) Patent Application Publication
(10) Pub. No.: US 2009/0162956 A1
(43) Pub. Date: Jun. 25, 2009

(54) LED FABRICATION METHOD EMPLOYING A WATER WASHING PROCESS

(75) Inventor: Victor Shi-Yueh Sheu, San-Chung City (TW)

Correspondence Address: PAI PATENT & TRADEMARK LAW FIRM, 1001 FOURTH AVENUE, SUITE 3200, SEATTLE, WA, 98154, US

(73) Assignee: ULT TECHNOLOGY CO., LTD., San-Chung City (TW)

(21) Appl. No.: 11/961,957

(22) Filed: Dec. 20, 2007

(51) Int. Cl. H01L 33/00

(52) U.S. Cl. 438/27; 257/E33.061

(57) ABSTRACT

An LED fabrication method for fabricating LEDs comprises: covering all the P-contacts and N-contacts on a wafer with a hydrophilic resin mask layer, packaging the wafer with an organic or inorganic polymer compound containing a yellow fluorescent powder (or a mixture of red and green fluorescent powders), employing a water washing process to remove the hydrophilic resin mask layer so that all the P-contacts and the N-contacts are exposed to the outside, and saw-cutting the wafer into individual dies and wire-bonding the P-contact and N-contact of each die with a respective gold wire.

### BACKGROUND OF THE INVENTION

(a) Field of the Invention

The present invention relates to the fabrication of LEDs and more particularly to an LED fabrication method that employs a water washing process so that the P-contact and N-contact are exposed to the outside of the package compound so that the LED thus made has excellent heat dissipation and a long service life and the bonded gold wires do not break so as to prevent a yellow border or halo.

(b) Description of the Prior Art

An LED (light emitting diode) wafer is prepared by growing a single crystal film on a properly heated substrate (sapphire, silicon carbonate, silicon) by means of MOCVD (Metal Organic Chemical Vapor Deposition). MOCVD is a standard tool for the growth of III-V or II-VI materials, for example, GaN (gallium nitride). It has come to maturity for many applications, such as industrial scale growth of blue, green, and ultraviolet LEDs.

According to conventional white LED fabrication methods, spot-gluing technique is employed to package LED dies with silicon rubber containing a yellow fluorescent powder (or a mixture of red and green fluorescent powders), thereby changing light of blue color to white color. This spot-gluing manufacturing process is not suitable for mass production. It consumes much labor and has the drawbacks of high defective rate and serious yellow halo problem.

Because the LED die is completely embedded in the package cup and the P and N contacts of the die are also embedded in the package cup, heat is not dissipated to the outside open air during light emitting operation, and the package cup of silicon rubber will soon metamorphize and lower the brightness. When the package cup cracks, the gold wires may break. Therefore, regular LEDs have the drawbacks of low brightness and short service life, and are suitable only for lower power applications, i.e., they are not practical for high power applications.

### SUMMARY OF THE INVENTION

The present invention has been accomplished under the circumstances in view.

According to one aspect of the present invention, the LED fabrication method is to cover all the P-contacts and N-contacts on a wafer with a hydrophilic resin mask layer, then to package the wafer with an organic or inorganic polymer compound containing a yellow fluorescent powder (or a mixture of red and green fluorescent powders), then to remove the hydrophilic resin mask layer by means of water washing so that all the P-contacts and the N-contacts are exposed to the outside, and then to employ wafer saw-cutting and gold wire bonding processed to finish the fabrication of white LEDs (or LEDs of other colors). Because the P-contact and the N-contact are not embedded in the polymer compound, heat can be quickly dissipated during working of the LED, and therefore the LED made according to the present invention has a long service life.

Because the invention employs a water washing process to remove the hydrophilic resin mask layer so that all the P-contacts and the N-contacts are exposed to the outside, the fabrication of LEDs is simple, and the LEDs thus made provide excellent heat dissipation and have a long service life. Therefore, the invention is suitable for mass production of LEDs of different colors.

According to another aspect of the present invention, the hydrophilic resin mask layer is covered on the P-contacts and N-contacts of the wafer by means of one of the techniques of spot-gluing, Coating, spray-painting, printing and transfer-printing.

According to still another aspect of the present invention, the organic or inorganic polymer compound containing a yellow fluorescent powder (or a mixture of red and green fluorescent powders) does not cover the P-contact and the N-contact, and therefore deterioration or metamorphism of the organic (or inorganic) polymer compound does not cause the gold wires to break, and therefore the emitted light will not be blocked and no yellow border or halo will occur.

### BRIEF DESCRIPTION OF THE DRAWINGS

FIG. 1 is an LED fabrication flow chart in accordance with the present invention.

FIG. 2 is a schematic drawing showing a P-contact and an N-contact located in a die according to the present invention.

FIG. 3 corresponds to FIG. 2, showing a hydrophilic resin mask layer covered on the P-contact and the N-contact.

FIG. 4 corresponds to FIG. 3, showing the surface of the wafer is packaged with a layer of an organic (or inorganic) polymer compound 3 that contains a yellow fluorescent powder (or a mixture of red and green fluorescent powders).

FIG. 5 corresponds to FIG. 4, showing the hydrophilic resin mask layer removed after water washing and the P-contact and the N-contact exposed to the outside.

FIG. 6 corresponds to FIG. 5, showing gold wires bonded to the P-contact and the N-contact.

### DETAILED DESCRIPTION OF THE PREFERRED EMBODIMENTS

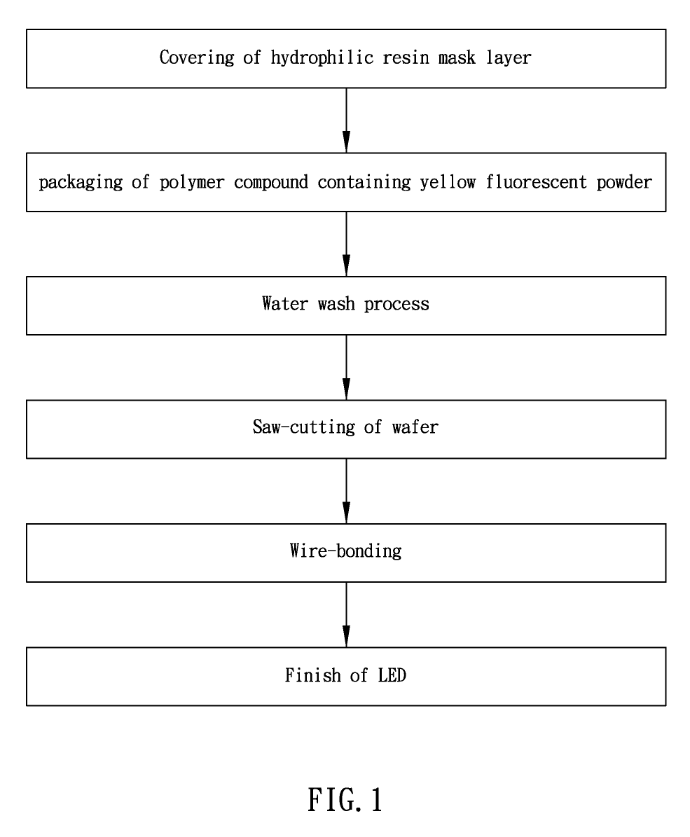

Referring to FIG. 1, an LED fabrication method in accordance with the present invention comprises the steps of covering all the P-contacts and N-contacts on a wafer with a hydrophilic resin mask layer, packaging the wafer with an organic or inorganic polymer compound containing a yellow fluorescent powder (or a mixture of red and green fluorescent powders), removing the hydrophilic resin mask layer by means of water washing so that all the P-contacts and the N-contacts are exposed to the outside, and employing wafer saw-cutting and gold wire-bonding processes to finish the fabrication of white LEDs (light emitting diodes). By means of the water washing process to have all the P-contacts and the N-contacts exposed to the outside, the LEDs thus made provide excellent heat dissipation and have a long service life. Further, the gold wires of the LEDs thus made do not break, thus preventing a yellow border or halo.

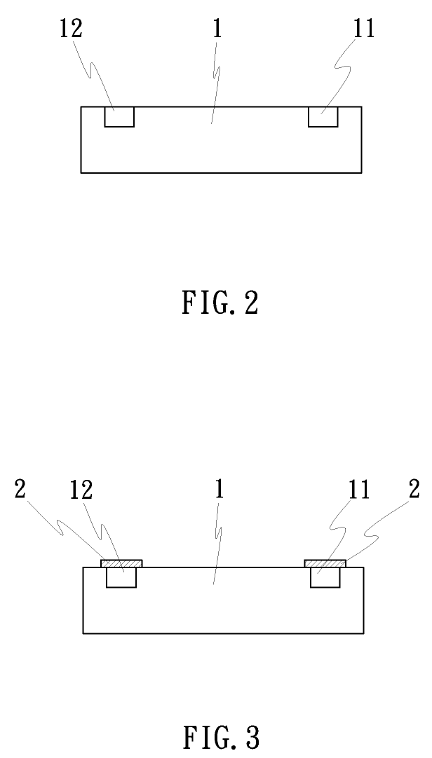

FIG. 2 is a schematic drawing showing a P-contact and an N-contact located in a die according to the present invention. In a GaN (gallium nitride) or other series semiconductor material 1, a P-contact 11 and an N-contact 12 are formed on each die. Before saw-cutting, a wafer has multiple dies on it.

FIG. 3 corresponds to FIG. 2, showing a hydrophilic resin mask layer covered on the die over the P-contact and the N-contact. As illustrated, a hydrophilic resin 2 is covered on each P-contact 11 and each N-contact 12 of the wafer, thereby forming a mask layer that is strippable by means of water washing. The hydrophilic resin 2 can be covered on each P-contact 11 and each N-contact 12 of the wafer by means of spot-gluing, coating, spray-painting, printing, or transfer-printing.

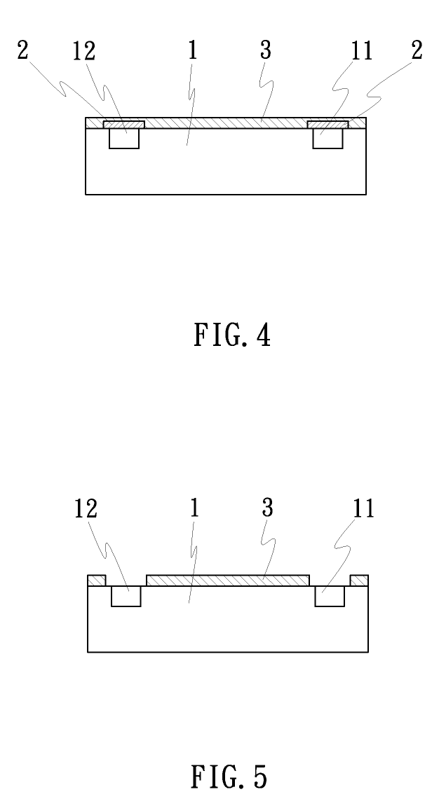

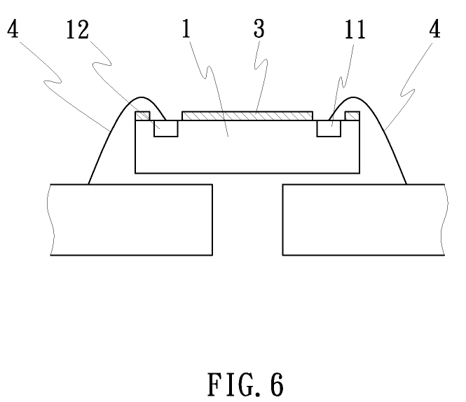

Referring to FIG. 4, the surface of the wafer is packaged with an organic (or inorganic) polymer compound 3 that contains a yellow fluorescent powder. Alternatively, the organic (or inorganic) polymer compound 3 contains a mixture of red and green fluorescent powders, or a mixture of multiple fluorescent powders having different colors.

The organic (or inorganic) polymer compound 3 can be packaged on the wafer by means of printing, coating, spray-painting, or transfer-printing.

After packaging of the layer of organic (or inorganic) polymer compound 3, a water washing process is employed to remove the mask layer of hydrophilic resin 2, exposing all the P-contacts 11 and the N-contacts 12 and leaving a layer of the organic (or inorganic) polymer compound 3 containing a yellow fluorescent powder (or a mixture of red and green fluorescent powders) on the surface of the wafer (see FIG. 5). Thereafter, a wafer saw-cutting process and gold wire 4 bonding process are employed to finish the white LEDs (light emitting diodes).

The hydrophilic resin 2 is an environmentally friendly material such as PVA, PVP, PULP, TALC, acrylic, silicon rubber, or melamine that is strippable with water washing.

According to the present invention, the mask layer of hydrophilic resin 2 that covers all the P-contacts 11 and the N-contacts 12 is strippable by means of water washing, and therefore the invention is suitable for mass production of white LEDs. This LED fabrication method does not cause any environmental protection problem, and has the advantages of low manufacturing cost and high yield rate. Because the P-contact 11 and the N-contact 12 are exposed to the outside, the LEDs have excellent heat dissipation and a long service life, and are practical for high-power high-illumination applications. Further, because the P-contact 11 and the N-contact 12 are not covered by the organic (or inorganic) polymer compound 3 containing a yellow fluorescent powder (or a mixture of red and green fluorescent powders), deterioration or aging of the organic (or inorganic) polymer compound does not cause the gold wires 4 to break, and therefore the emitted light will not be blocked and no yellow border or halo will occur.

Although a particular embodiment of the invention has been described in detail for purposes of illustration, various modifications and enhancements may be made without departing from the spirit and scope of the invention. Accordingly, the invention is not to be limited except as by the appended claims.

What is claimed is:

1. An LED fabrication method comprising the steps of:
covering all P-contacts and N-contacts of a wafer with a hydrophilic resin mask layer;
packaging said wafer with a polymer compound containing a fluorescent powder;
removing said hydrophilic resin mask layer by means of water washing so that said P-contacts and said N-contacts are exposed to the outside;
saw-cutting said wafer into individual dies, each having a P-contact and an N-contact; and
wire-bonding the P-contact and the N-contact of said individual die with gold wires.

2. The LED fabrication method as claimed in claim 1, wherein the fluorescent powder of said polymer compound is a yellow fluorescent powder.

3. The LED fabrication method as claimed in claim 1, wherein the fluorescent powder of said polymer compound is a mixture of a red fluorescent powder and a green fluorescent powder.

4. The LED fabrication method as claimed in claim 1, wherein the fluorescent powder of said polymer compound is a mixture of multiple fluorescent powders having different colors.

5. The LED fabrication method as claimed in claim 1, wherein said hydrophilic resin mask layer is covered on the P-contacts and N-contacts of said wafer by means of one of the group of techniques consisting of spot-gluing, coating, spray-painting, printing and transfer-printing.

6. The LED fabrication method as claimed in claim 1, wherein said wafer is packed with said polymer compound containing a fluorescent powder by means of one of the group of techniques consisting of spot-gluing, coating, spray-painting, printing and transfer-printing.
